(19) United States
(12) Patent Application Publication
(10) Pub. No.: US 2026/0007032 A1
(43) Pub. Date: Jan. 1, 2026

(54) ELECTRONIC DEVICE

(71) Applicant: Samsung Display Co., Ltd., Yongin-si (KR)

(72) Inventors: KYUNGHEE LEE, Yongin-si (KR); TAEMIN KIM, Yongin-si (KR); DONGGEUN SHIN, Yongin-si (KR); SEUNGHEE LEE, Yongin-si (KR)

(21) Appl. No.: 19/242,169

(22) Filed: Jun. 18, 2025

(30) Foreign Application Priority Data
Jun. 26, 2024 (KR) 10-2024-0083962
Dec. 6, 2024 (KR) 10-2024-0180796

(51) Int. Cl. H10K 59/38; H10K 59/80

(52) U.S. Cl. CPC H10K 59/38; H10K 59/873; H10K 59/8792

(57) ABSTRACT

Provided is an electronic device including a display panel, a light control layer on the display panel and including quantum dots, a color filter layer on the light control layer, and an overcoat layer on the color filter layer. The overcoat layer may include a first organic overcoat layer on the color filter layer and including a polymer derived from a resin composition including a base resin and a polyol compound, a first inorganic overcoat layer on the first organic overcoat layer, and a second organic overcoat layer on the first inorganic overcoat layer and including the polymer.

### CROSS-REFERENCE TO RELATED APPLICATIONS

The present application claims priority to and the benefit of Korean Patent Application No. 10-2024-0083962, filed on Jun. 26, 2024, and Korean Patent Application No. 10-2024-0180796, filed on Dec. 6, 2024, in the Korean Intellectual Property Office, the entire disclosures of which are hereby incorporated by reference.

### BACKGROUND

Embodiments of the present disclosure herein relate to an electronic device.

Multimedia electronic devices such as televisions, mobile phones, tablet computers, navigation devices, game consoles, and wearable devices may include a display module to display images. Electronic devices may incorporate a suitable variety of optical functional layers to provide users with high-quality color images. In recent years, there has been research into thin electronic devices to develop various suitable types or kinds of display devices, including those having curved surfaces, rollable electronic devices, and/or foldable electronic devices.

### SUMMARY

Embodiments of the present disclosure provide an electronic device featuring superior display quality.

An embodiment of the present disclosure provides an electronic device including a display panel, a color filter layer on the display panel, and an overcoat layer on the color filter layer where the overcoat layer includes a first organic overcoat layer on the color filter layer and including a polymer derived from a resin composition including a base resin and a polyol compound, a first inorganic overcoat layer on the first organic overcoat layer, and a second organic overcoat layer on the first inorganic overcoat layer and including the polymer.

In an embodiment, the first inorganic overcoat layer may include at least one of silicon oxide or silicon nitride.

In an embodiment, the first inorganic overcoat layer may include at least one of a first inorganic film including silicon oxide or a second inorganic film including silicon nitride.

In an embodiment, in the first inorganic overcoat layer, the first inorganic film and the second inorganic film may be alternately provided on the first organic overcoat layer in a plurality of layers.

In an embodiment, the first inorganic overcoat layer may include a first inorganic film on the first organic overcoat layer and including silicon oxide, a second inorganic film on the first inorganic film and including silicon nitride, a third inorganic film on the second inorganic film and including silicon oxide, and a fourth inorganic film on the third inorganic film and including silicon nitride.

In an embodiment, the overcoat layer may further include a low refractive index layer on the second organic overcoat layer.

In an embodiment, the overcoat layer may further include a second inorganic overcoat layer on the second organic overcoat layer, and a third organic overcoat layer on the second inorganic overcoat layer.

In an embodiment, the second inorganic overcoat layer may include at least one of silicon oxide or silicon nitride.

In an embodiment, the first organic overcoat layer and the second organic overcoat layer may each have a thickness of about 0.5 μm to about 20 μm.

In an embodiment, the color filter layer may include a first color filter transmitting red light, a second color filter transmitting green light, and a third color filter transmitting blue light, and the first organic overcoat layer may be in direct contact with the first color filter, the second color filter, and the third color filter.

In an embodiment, the second color filter may comprise a colorant which exhibits an emission wavelength spectrum having a full width at half maximum (FWHM) of about 70 nm or less, and the third color filter may comprise a colorant which exhibits an emission wavelength spectrum having a full width at half maximum (FWHM) of about 100 nm or less.

In an embodiment, the base resin may include at least one of a polysilsesquioxane compound or a polysiloxane compound.

In an embodiment, the base resin may include a polysilsesquioxane compound, and the polysilsesquioxane compound may be provided in an amount of about 30 wt % to about 50 wt % with respect to a total weight of the resin composition.

In an embodiment, the polyol compound may be provided in an amount of greater than about 0 wt % and about 10 wt % or less with respect to a total weight of the resin composition.

In an embodiment of the present disclosure, an electronic device may include a display panel that outputs source light and includes a first light emitting region, a second light emitting region, and a third light emitting region, which are spaced apart on a plane and sequentially provided in a first direction, and a light control panel on the display panel that transmits the source light or converts a wavelength of the source light where the light control panel may include first to third color filters provided corresponding to the first to third light emitting regions, respectively, and an overcoat layer on the first to third color filters, and the overcoat layer includes a first organic overcoat layer that covers the first to third color filters, a second organic overcoat layer that faces the first organic overcoat layer, and a first inorganic overcoat layer between the first organic overcoat layer and the second organic overcoat layer.

In an embodiment, the first inorganic overcoat layer may include at least one first inorganic film including silicon oxide, and at least one second inorganic film including silicon nitride.

In an embodiment, in the first inorganic overcoat layer, the first inorganic film and the second inorganic film may be alternately provided in a plurality of layers.

In an embodiment, the light control panel may further include a light control layer between the display panel and the first to third color filters where the light control layer may include a first light control portion corresponding to the first light emitting region and including a first quantum dot that converts the source light into light of a different wavelength, a second light control portion corresponding to the second light emitting region and including a second quantum dot that converts the source light into light of a different wavelength, and a third light control portion corresponding to the third light emitting region and that transmits the source light.

In an embodiment, the first organic overcoat layer and the second organic overcoat layer may each include a polymer derived from a resin composition including a polysilsesquioxane compound and a polyol compound.

In an embodiment, the light control panel may further include an anti-reflection layer on the overcoat layer.

### BRIEF DESCRIPTION OF THE DRAWINGS

The accompanying drawings are included to provide a further understanding of embodiments of the present disclosure, and are incorporated in and constitute a part of this specification. The drawings illustrate embodiments of the present disclosure and, together with the description, serve to explain principles of the present disclosure. In the drawings:

FIG. 1 is a perspective view showing an electronic device of an embodiment;

FIG. 2 is a perspective view showing a display module of an embodiment;

FIG. 3 is a cross-sectional view showing a display module of an embodiment;

FIG. 4 is a plan view showing a display module of an embodiment;

FIG. 5 is a plan view showing a portion of a display module of an embodiment;

FIGS. 6A and 6B are each a cross-sectional view showing a portion of a display module according to an embodiment;

FIG. 7A is a cross-sectional view schematically showing an overcoat layer of an embodiment;

FIG. 7B is a cross-sectional view schematically showing an overcoat layer of an embodiment;

FIG. 7C is a cross-sectional view schematically showing an overcoat layer of an embodiment;

FIG. 7D is a cross-sectional view schematically showing an overcoat layer of an embodiment; and

FIG. 7E is a cross-sectional view schematically showing an overcoat layer of an embodiment.

### DETAILED DESCRIPTION

In this specification, it will be understood that when an element (or a region, a layer, a portion, or the like) is referred to as being “on”, “connected to” or “coupled to” another element, it may be directly on, connected to, or coupled to the other element, or other elements may be therebetween.

Like reference numerals or symbols refer to like elements throughout. In the drawings, the thickness, ratio, and size of the elements may be exaggerated for effectively describing the technical contents. As used herein, the term “and/or” includes any and all combinations of one or more of the associated listed elements.

It will be understood that, although the terms “first”, “second”, and/or the like may be used herein to describe various elements, the elements are not to be limited by these terms. These terms are only used to distinguish one element from another element. For instance, a first element could be termed a second element without departing from the scope of the present disclosure. Similarly, a second element could be termed a first element. In this specification, the singular expressions “a”, “an” and “the” are intended to include the plural forms as well, unless the context clearly indicates otherwise.

In embodiments, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, being “directly on” may indicate that there is no additional layer, film, region, plate, or the like between a part and another part such as a layer, a film, a region, a plate, or the like. For example, being “directly on” may indicate that two layers or two members are provided without using an additional member such as an adhesive member, therebetween.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display module and an electronic device according to an embodiment of the present disclosure will be described with reference to the accompanying drawings.

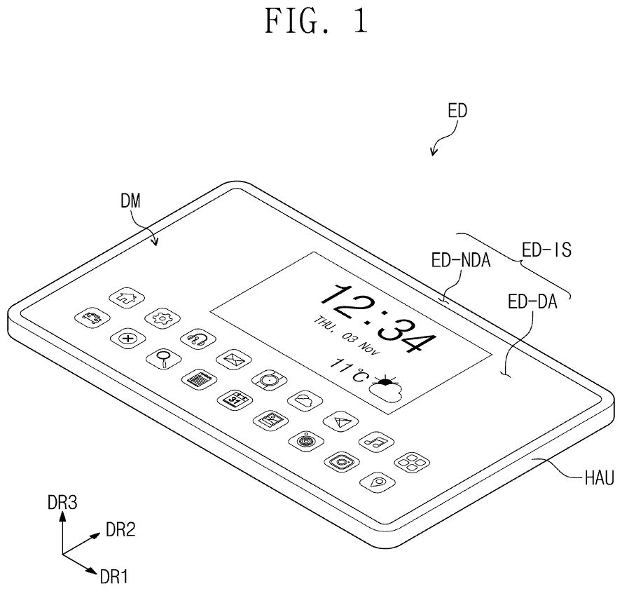

FIG. 1 is a perspective view showing an electronic device of an embodiment. As shown in FIG. 1, the electronic device ED may include a display module DM that displays images through a display surface ED-IS. The display module DM may be housed and provided in a housing HAU.

When viewed on a plane, the display surface ED-IS of the electronic device ED may have a rectangular shape which has long sides that extend in a first direction DR1 and short sides that extend in a second direction DR2 crossing the first direction DR1. However, embodiments of the present disclosure are not limited thereto, and the display surface ED-IS may have various suitable shapes such as a circular (e.g., generally circular) shape or a polygonal shape.

In embodiments, a third direction DR3 may be defined as a direction substantially perpendicular to a plane defined by the first direction DR1 and the second direction DR2. A front surface (or upper surface) and a rear surface (or lower surface) of each member constituting the electronic device ED may oppose each other in the third direction DR3 and a normal direction of each of the front and rear surfaces may substantially be parallel to the third direction DR3. A distance between the front surface and the rear surface defined along the third direction DR3 may correspond to a thickness of a member.

In embodiments, the phrase “on a plane” may be defined as a state viewed in the third direction DR3. For example, the phrase “on a plane” may be described with respect to the plane defined by both the first direction DR1 and the second direction DR2. In embodiments, the phrase “on a cross-section” may be defined as a state viewed in the first direction DR1 or the second direction DR2. Directions indicated by the first to third directions DR1, DR2, and DR3 are relative concepts, and may thus be changed to other directions.

An electronic device ED including the display module DM provided having a flat display surface is shown in an embodiment, but embodiments of the present disclosure are not limited thereto. The electronic device ED may include a curved display surface and/or a three-dimensional display surface. For example, the three-dimensional display surface may include a plurality of display regions indicating different directions, and may also include a bent display surface. The electronic device ED according to an embodiment may be a flexible electronic device. The term “flexible” indicates the property of being able to bend. For example, the flexible electronic device ED may include a curved electronic device, a rollable electronic device, and/or a foldable electronic device.

In FIG. 1, a tablet terminal is shown as an example of the electronic device ED. The tablet terminal may be formed by placing electronic modules, camera modules, power modules, and/or the like mounted on a motherboard in a bracket/case along with the display module DM. Embodiments of the present disclosure, however, are not limited thereto, and the display module DM may not only be used for large-sized electronic devices such as television sets, outdoor billboards, and/or monitors but also used for small-and/or medium-sized electronic devices such as mobile phones, car navigation systems, game consoles, and smart watches. In embodiments, these devices are merely presented as examples, and other electronic devices may be employed as long as not departing from the spirit or scope of the present disclosure. The electronic device ED including the display module DM may also be referred to as a display device.

As shown in FIG. 1, the display surface ED-IS includes an active region ED-DA on which images are displayed and a bezel region ED-NDA adjacent to the active region ED-DA. The bezel region ED-NDA is a region on which images are not displayed. In FIG. 1, icon images are shown as an example of images. The active region ED-DA may be referred to as a display region of the display module DM, and the bezel region ED-NDA may be referred to as a non-display region of the display module DM.

As shown in FIG. 1, the active region ED-DA may have a substantially quadrangular shape. The term “substantially quadrangular shape” may include not only a quadrangular shape having mathematical meaning but also a quadrangular shape in which not a vertex but a curved boundary is defined in a vertex region (a corner region).

The bezel region ED-NDA may be around (e.g., surround) the active region ED-DA. However, embodiments of the present disclosure are not limited thereto, and the bezel region ED-NDA may be modified in shape. For example, the bezel region ED-NDA may be on only one side of the active region ED-DA.

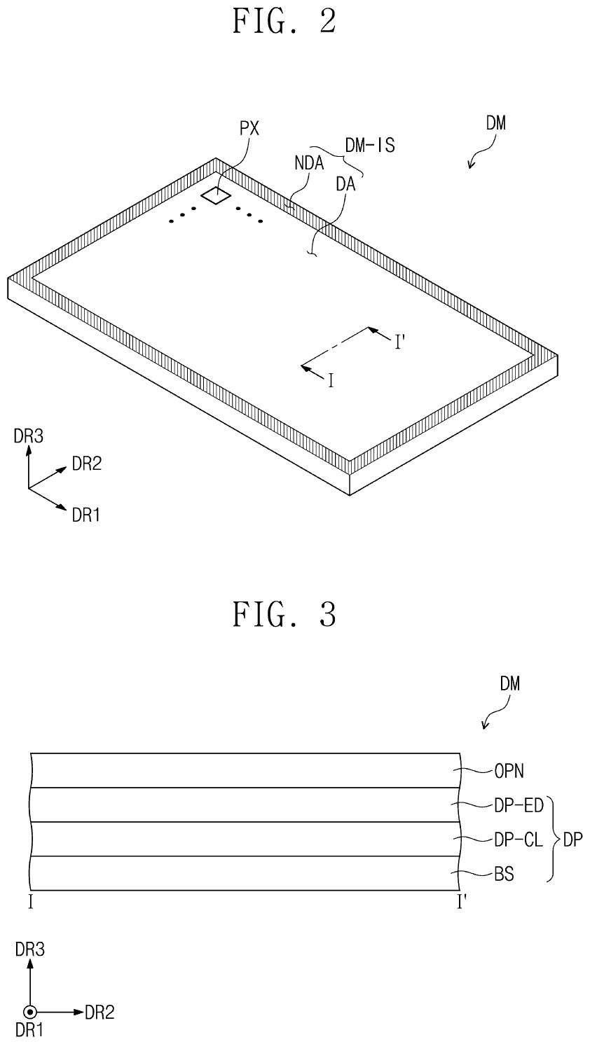

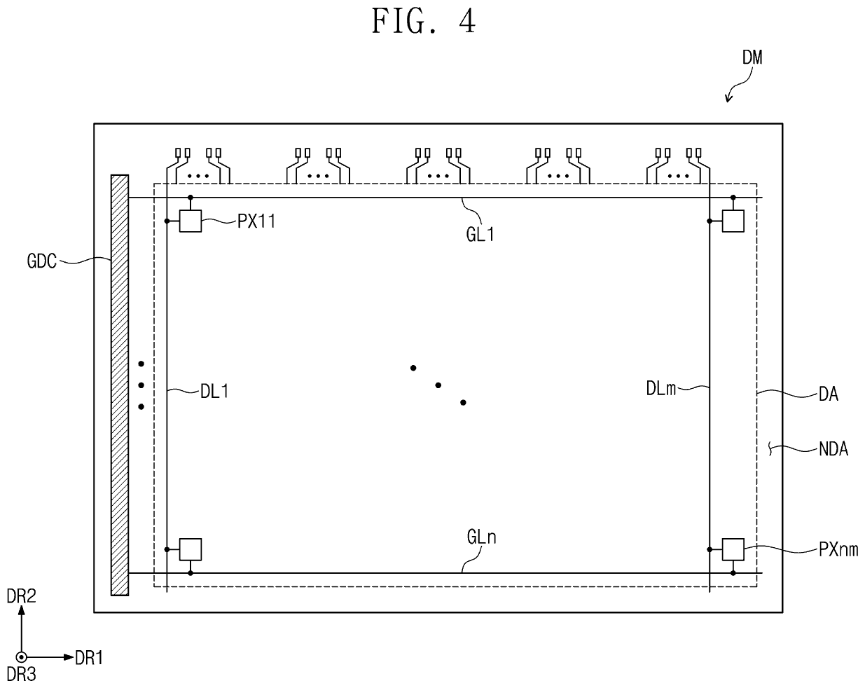

FIG. 2 is a perspective view showing a display module of an embodiment. FIG. 3 is a cross-sectional view showing a display module of an embodiment. FIG. 3 may be a cross-sectional view schematically showing a portion corresponding to line I-I′ of FIG. 2. FIG. 4 is a plan view showing a display module of an embodiment.

Referring to FIG. 2, the display module DM may include a display surface DM-IS, and the display module DM may display images through the display surface DM-IS. The display surface ED-IS may be parallel to a plane defined by a first direction DR1 and a second direction DR2. The display surface DM-IS of the display module DM may correspond to the display surface ED-IS of the electronic device ED.

The display surface DM-IS may include a display region DA and a non- display region NDA. A plurality of pixels PX may be provided in the display region DA. Each of the pixels PX may include a plurality of sub-pixels. The non-display region NDA may be a portion in which the pixels PX are not provided. The non-display region NDA may be defined along an edge of the display surface DM-IS. The non-display region NDA may be around (e.g., surround) the display region DA. However, embodiments of the present disclosure are not limited thereto, and the non-display region NDA may not be provided, or the non-display region NDA may be provided only on one side of the display region DA.

Referring to FIG. 3, the display module DM may include a display panel DP and a light control panel OPN on the display panel DP. The display panel DP may include a base substrate BS, a circuit layer DP-CL on the base substrate BS, and a display element layer DP-ED on the circuit layer DP-CL. In the display module DM of an embodiment, the light control panel OPN may be directly on the display element layer DP-ED. In an embodiment, the display panel DP may be referred to as a lower panel or a lower display substrate, and the light control panel OPN may be referred to as an upper panel or an upper display substrate.

Although not shown in FIG. 3, in some embodiments, a filling layer may be between the display panel DP and the light control panel OPN. The display panel DP and the light control panel OPN may be spaced apart with the filling layer therebetween. In embodiments, the light control panel OPN may be manufactured in a separate process and then provided on the display panel DP.

In embodiments, in the display module DM of an embodiment, the light control panel OPN may be directly on the display element layer DP-ED. In embodiments, when a component is ‘directly provided/directly formed’ on another component, it indicates that a third component is not between one component and another component. For example, when a component is ‘directly placed/directly formed’ on another component, it indicates that a component is in ‘contact’ with another component.

The base substrate BS may be a member that provides a base surface on or in which the circuit layer DP-CL and the display element layer DP-ED are provided. The circuit layer DP-CL may include at least one insulating layer (e.g., electrically insulating layer) and a circuit element. The circuit element may include signal lines, pixel driving circuits, and/or the like. The circuit layer DP-CL may be formed through a process of forming an insulating layer (e.g., an electrically insulating layer), a semiconductor layer, and a conductive layer (e.g., an electrically conductive layer) by coating, vapor deposition, and/or the like, and a process of patterning the insulating layer, the semiconductor layer, and the conductive layer by photolithography.

The display element layer DP-ED includes display elements. The display device may include a light emitting element that generates light and provides the light to the light control panel OPN. The display panel DP including the display element layer DP-ED may provide source light to the light control panel OPN on an upper portion.

The light control panel OPN may convert a wavelength of the light provided from the display panel DP or transmit a portion of the provided light. The light control panel OPN may include a light control portion that converts or transmits wavelengths, and structures designed to increase the conversion efficiency of emitted light.

FIG. 4 shows a planar arrangement relationship of signal lines GL1 to GLn and DL1 to DLm, pixels PX11 to PXnm, and gate driving circuit GDC. The signal lines GL1 to GLn and DL1 to DLm may include a plurality of gate lines GL1 to GLn and a plurality of data lines DL1 to DLm.

The pixels PX11 to PXnm are each electrically connected to a corresponding gate line among the plurality of gate lines GL1 to GLn and a corresponding data line among the plurality of data lines DL1 to DLm. The pixels PX11 to PX may each include a pixel driving circuit and a display element. More various suitable types or kinds of signal lines may be provided in the display panel DP according to the configuration of the pixel driving circuits of the pixels PX11 to PXnm. The gate driving circuit GDC may be integrated on the display panel DP through an oxide silicon gate (OSG) driver circuit process or an amorphous silicon gate (ASG) driver circuit process.

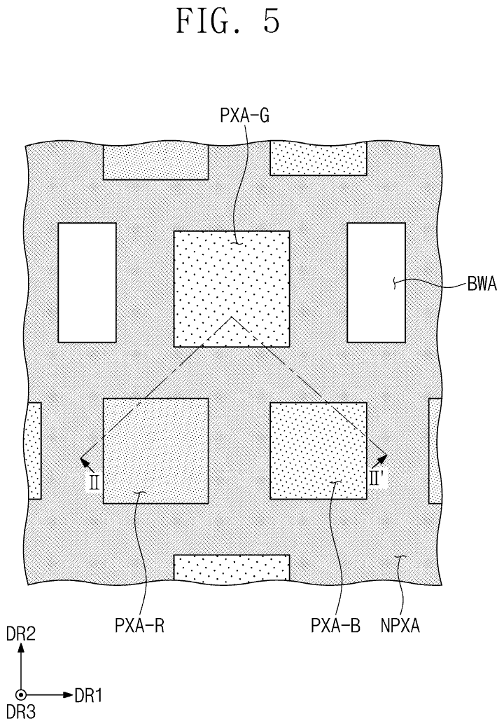

FIG. 5 is a plan view showing a portion of a display module of an embodiment. FIG. 5 is a plan view enlarging a portion of a display module according to an embodiment. FIG. 5 shows an arrangement relationship of a plurality of pixel regions provided in the display region DA (FIG. 2) in the display module DM (FIG. 2) of an embodiment. In an embodiment, three pixel regions PXA-R, PXA-G, and PXA-B shown in FIG. 5 may be repeatedly provided throughout the display region DA (FIG. 2). The pixel regions PXA-R, PXA-G, and PXA-B may also be referred to as light emitting regions.

In an embodiment, the electronic device ED (FIG. 1) may include a first pixel region PXA-R, a second pixel region PXA-G, and a third pixel region PXA-B, which emit light in different wavelength ranges. The first to third pixel regions PXA-R, PXA-G, and PXA-B may not overlap and be separated from one another when viewed on a plane.

The first pixel region PXA-R may emit light having a light emitting wavelength of about 610 nm to about 700 nm, the second pixel region PXA-G may emit light having a light emitting wavelength of about 500 nm to about 590 nm, and the third pixel region PXA-B may emit light having a light emitting wavelength of about 410 nm to about 480 nm.

In an embodiment, the first pixel region PXA-R may be a red pixel region that emits red light, the second pixel region PXA-G may be a green pixel region that emits green light, and the third pixel region PXA-B may be a blue pixel region that emits blue light. However, embodiments of the present disclosure are not limited thereto, and in an embodiment, the display region DA may further include a pixel region that emits white light, in addition to the first to third pixel regions PXA-R, PXA-G, and PXA-B.

In an embodiment, one pixel PX (FIG. 2) may be formed by grouping one first pixel region PXA-R, one second pixel region PXA-G, and one third pixel region PXA-B. The arrangement of pixel regions shown in FIG. 5 is presented as an example, and other than the illustrated embodiment, one pixel PX (FIG. 2) may further include pixel regions that emit light of a different wavelength range in addition to the first to third pixel regions PXA-R, PXA-G, and PXA-B. In embodiments, two or more of at least one of the first to third pixel regions PXA-R, PXA-G, and PXA-B may be included in one pixel PX.

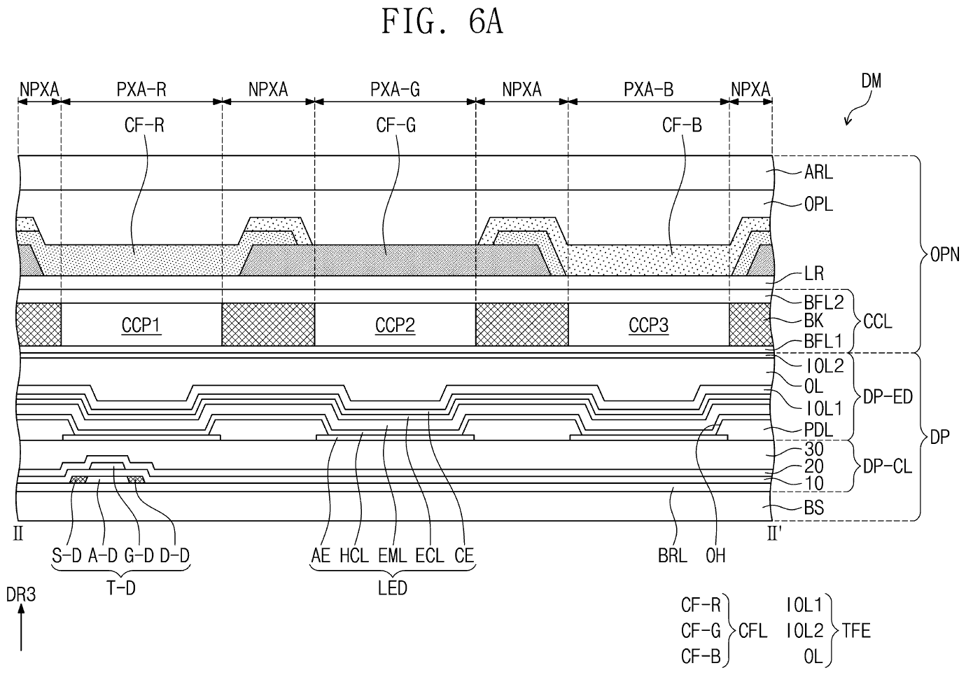

A peripheral region NPXA is around the first to third pixel regions PXA-R, PXA-G, and PXA-B. The peripheral region NPXA may be referred to as a non-light emitting region. The peripheral region NPXA may be around (e.g., surround) each of the first pixel region PXA-R, the second pixel region PXA-G, and the third pixel region PXA-B. The peripheral region NPXA may set a border among the first to third pixel regions PXA-R, PXA-G, and PXA-B to prevent or reduce color mixing of the first to third pixel regions PXA-R, PXA-G, and PXA-B. A structure that prevents or reduces color mixing between the first to third pixel regions PXA-R, PXA-G, and PXA-B, for example, a pixel defining film PDL (FIGS. 6A and 6B) or a division pattern BK (FIGS. 6A and 6B) may be provided in the peripheral region NPXA.

In FIG. 5, the first to third pixel regions PXA-R, PXA-G, and PXA-B of an embodiment are shown as having the same shape on a plane and different areas on a plane, but embodiments of the present disclosure are not limited thereto. The areas of at least two pixel regions among the first to third pixel regions PXA-R, PXA-G, and PXA-B may be equal to each other. The areas of the first to third pixel regions PXA-R, PXA-G, and PXA-B may be set according to the color of emitted light. In embodiments, the area may indicate an area when viewed on a plane defined by the first direction DR1 and the second direction DR2. For example, among the primary colors, the area of the second pixel region PXA-G that emits green light may be the largest, and the area of the third pixel region PXA-B that emits blue light may be the smallest.

In an embodiment shown in FIG. 5, the first to third pixel regions PXA-R, PXA-G, and PXA-B may each have a rectangular shape on a plane. Unlike the case above, the first to third pixel regions PXA-R, PXA-G, and PXA-B may have any other polygonal shapes such as a rhombus or a pentagon. In embodiments, the first to third pixel regions PXA-R, PXA-G, and PXA-B may each have a rectangular shape having rounded corners. In embodiments, the first to third pixel regions PXA-R, PXA-G, and PXA-B may have different shapes when viewed on a plane.

FIG. 5 shows that the second pixel region PXA-G is provided in a first row, and the first pixel region PXA-R and the third pixel region PXA-B are provided in a second row. However, this is presented as an example, and the arrangement of the first to third pixel regions PXA-R, PXA-G, and PXA-B may be changed in various suitable ways. For example, the first to third pixel regions PXA-R, PXA-G, and PXA-B may be provided in the same row.

A bank well region BWA may be defined in the display region DA (FIG. 2). The bank well region BWA may be a region formed to prevent or reduce defects caused by misprinting in a process of printing some of a plurality of light control portions CCP1, CCP2, and CCP3 included in the light control layer CCL (FIGS. 6A and 6B). For example, the bank well region BWA may be a region formed by removing a portion of the division pattern BK (FIGS. 6A and 6B). FIG. 5 shows that two bank well regions BWA are formed to be adjacent to the second pixel region PXA-G, but embodiments of the present disclosure are not limited thereto, and the shape and arrangement of the bank well region BWA may be variously, suitably changed. In embodiments, the bank well region BWA may not be provided.

FIGS. 6A and 6B are each cross-sectional views showing a portion of a display module according to an embodiment. FIGS. 6A and 6B may each correspond to cross sections corresponding to cutting line II-II′ shown in FIG. 5. FIGS. 6A and 6B show cross sections of display modules corresponding to three neighboring pixel regions. The display module of an embodiment shown in FIG. 6B differs from the display module of an embodiment shown in FIG. 6A, in terms of the configuration of a light control panel.

Referring to FIGS. 6A and 6B, the display panel DP of an embodiment may include a base substrate BS, a circuit layer DP-CL on the base substrate BS, and a display element layer DP-ED on the circuit layer DP-CL. The display element layer DP-ED may include a light emitting element LED and an encapsulation layer TFE that covers an upper portion of the light emitting element LED. The light control panel OPN may include a light control layer CCL, color filter layers CFL and CFL-1, an overcoat layer OPL, and an anti-reflection layer ARL on the display element layer DP-ED.

In the display panel DP of an embodiment, the base substrate BS may be a member that provides a reference surface on which components included in the circuit layer DP-CL are provided. In an embodiment, the base substrate BS may be a glass substrate, a metal substrate, a polymer substrate, and/or the like. However, embodiments of the present disclosure are not limited thereto, and the base substrate BS may be an inorganic layer, a functional layer, or a composite material layer (e.g., including an inorganic layer and a functional layer).

The base substrate BS may have a multilayer structure. For example, the base substrate BS may have a three-layer structure of a polymer resin layer, an adhesive layer, and a polymer resin layer. In embodiments, the polymer resin layer may include a polyimide-based resin. In embodiments, the polymer resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. As used herein, a “ . . . ”-based resin indicates that a functional group of “ . . . ” is included in the resin.

The circuit layer DP-CL may be on the base substrate BS, and the circuit layer DP-CL may include a transistor T-D as a circuit element. The configuration of the circuit layer DP-CL may suitably vary depending on the design of the driving circuit of the pixel PX (FIG. 2), and in an embodiment, the circuit layer DP-CL may include a plurality of types or kinds of transistors having different functions.

FIGS. 6A and 6B show one transistor T-D as an example. In an embodiment, the transistor T-D may be a driving transistor or a switching transistor, which is electrically connected to the light emitting element LED. In FIGS. 6A and 6B, an arrangement relationship of an active A-D, a source S-D, a drain D-D, and a gate G-D, which constitute the transistor T-D, is shown as an example. The active A-D, the source S-D, and the drain D-D may be regions divided according to the doping concentration and/or conductivity (e.g., electrical conductivity) of a semiconductor pattern.

In the transistor T-D of an embodiment, the semiconductor pattern may include a metal oxide. For example, the semiconductor pattern constituting the active A-D, the source S-D, and the drain D-D of the transistor T-D may include a metal oxide including at least one of indium, gallium, zinc, tin, or titanium. In embodiments, although only one transistor T-D is illustrated in FIGS. 6A and 6B, the circuit layer DP-CL may include a plurality of transistors, and at least one of the plurality of transistors may include a metal oxide in the semiconductor pattern. In embodiments, in an embodiment of the transistor T-D, the gate G-D may have a top gate structure on an upper portion of the semiconductor pattern.

The circuit layer DP-CL may include a lower buffer layer BRL on the base substrate BS, a first insulating layer 10 (e.g., a first electrically insulating layer) on the lower buffer layer BRL, a second insulating layer 20 (e.g., a second electrically insulating layer) on the first insulating layer 10, and a third insulating layer 30 on the second insulating layer 20. For example, the lower buffer layer BRL, the first insulating layer 10, and the second insulating layer 20 may be inorganic layers, and the third insulating layer 30 may be an organic layer. The semiconductor pattern constituting the active A-D, the source S-D, and the drain D-D may be provided on the lower buffer layer BRL and covered with the first insulating layer 10. The gate G-D may be provided on the first insulating layer 10 and covered with a second insulating layer 20.

The display element layer DP-ED may include the light emitting element LED as a display element and may include the pixel definition film PDL in which a light emitting opening OH is defined. In embodiments, the display element layer DP-ED may include the encapsulation layer TFE on the light emitting element LED.

The light emitting element LED may generate source light. The source light generated and emitted from the light emitting element LED may be provided to the light control panel OPN, and at least a portion of the source light may be converted into light having a wavelength different from a wavelength of the source light in the light control layer CCL of the light control panel OPN, or at least a portion of the source light may be transmitted without wavelength conversion.

In an embodiment, the source light may include blue light. In an embodiment, the source light may be a mixture of blue light and light in a wavelength range other than blue light. In an embodiment, the display element layer DP-ED may include an organic light emitting diode as the light emitting element LED. The light emitting element LED may include organic light emitting materials as a light emitting material.

The light emitting element LED may include a first electrode AE exposed at the light emitting opening OH, a second electrode CE that faces the first electrode AE, and an emission layer EML between the first electrode AE and the second electrode CE. The light emitting element LED may include a hole transport region HCL between the first electrode AE and the emission layer EML, and an electron transport region ECL between the emission layer EML and the second electrode CE.

The first electrode AE may be conductive (e.g., electrically conductive). The first electrode AE may be formed of a metal material, a metal alloy, and/or a conductive compound (e.g., an electrically conductive compound). The first electrode AE may be a cathode or an anode. However, embodiments of the present disclosure are not limited thereto. In embodiments, the first electrode AE may be a pixel electrode. The first electrode AE may be a transmissive electrode, a transflective electrode, or a reflective electrode. The first electrode may include at least one selected from Ag, Mg, Cu, Al, Pt, Pd, Au, Ni, Nd, Ir, Cr, Li, Ca, LiF, Mo, Ti, W, In, Sn, or Zn, at least two compounds selected therefrom, two or more mixtures selected therefrom, or an oxide thereof.

When the first electrode AE is the transmissive electrode, the first electrode AE may include a transparent metal oxide such as indium tin oxide (ITO), indium zinc oxide (IZO), zinc oxide (ZnO), and/or indium tin zinc oxide (ITZO). When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, or a compound or a mixture thereof (e.g., a mixture of Ag and Mg). In embodiments, the first electrode AE may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode AE may have a three-layer structure of ITO/Ag/ITO, but is not limited thereto. In embodiments, the first electrode AE may include the above-described metal materials, a combination of two or more metal materials selected from the above-described metal materials, or oxides of the above-described metal materials, and embodiments of the present disclosure are not limited thereto.

The hole transport region HCL may have a single layer formed of a single material, a single layer formed of a plurality of different materials, or a multilayer structure having a plurality of layers formed of a plurality of different materials. The hole transport region HCL may include any suitable hole injection materials generally used in the art and/or any suitable hole transport materials generally used in the art. The hole transport region HCL may include at least one of a hole injection layer, a hole transport layer, or an electron blocking layer.

The emission layer EML may emit source light including blue light. The emission layer EML may also emit source light including blue light and green light. The emission layer EML may include an organic light emitting material and/or an inorganic light emitting material. For example, the emission layer EML may include a fluorescence emission material and/or a phosphorescence emission material. In embodiments, the emission layer EML may include quantum dots as a light emitting material.

The electron transport region ECL may have a single layer formed of a single material, a single layer formed of a plurality of different materials, or a multilayer structure having a plurality of layers formed of a plurality of different materials. The electron transport region ECL may include any suitable electron injection materials generally used in the art and/or any suitable electron transport materials generally used in the art. The electron transport region ECL may include at least one of an electron injection layer, an electron transport layer, or a hole blocking layer.

Although FIGS. 6A and 6B show that the hole transport region HCL, the emission layer EML, and the electron transport region ECL are provided as a common layer, embodiments of the present disclosure are not limited thereto. For example, the hole transport region HCL, the emission layer EML, and/or the electron transport region ECL may be provided by being patterned within the light emitting opening OH defined in the pixel defining film PDL.

The second electrode CE may be a common electrode. The second electrode CE may be a cathode or an anode, but embodiments of the present disclosure are not limited thereto. For example, when the first electrode AE is an anode, the second electrode CE may be a cathode, and when the first electrode AE is a cathode, the second electrode CE may be an anode. The second electrode CE may include at least one selected from Ag, Mg, Cu, Al, Pt, Pd, Au, Ni, Nd, Ir, Cr, Li, Ca, LiF, Mo, Ti, W, In, Sn, and Zn, at least two compounds selected therefrom, two or more mixtures selected therefrom, or an oxide thereof.

The second electrode CE may be a transmissive electrode, a transflective electrode, or a reflective electrode. When the second electrode CE is a transmissive electrode, the second electrode CE may be formed of a transparent metal oxide, for example, indium tin oxide (ITO), indium zinc oxide (IZO), zinc oxide (ZnO), indium tin zinc oxide (ITZO), and/or the like.

When the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, a compound thereof, or a mixture thereof (e.g., AgMg, AgYb, and/or MgYb). In embodiments, the second electrode CE may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the second electrode CE may include the above- described metal materials, a combination of two or more metal materials selected from the above-described metal materials, or oxides of the above-described metal materials.

In embodiments, an element capping layer may be provided on the second electrode CE. The element capping layer may be a single layer or a multilayer. The element capping layer may include an inorganic material such as an alkali metal compound such as LiF, an alkaline earth metal compound such as MgF₂, SiON, SiN_{X}, SiO_{y}, and/or the like. Unlike what is described above, the element capping layer may include an organic material such as α-NPD, NPB, TPD, m-MTDATA, Alq₃ CuPc, N4, N4, N4′, N4′-tetra(biphenyl-4-yl) biphenyl-4,4′-diamine (TPD15), 4,4′,4″-tris(carbazol-9-yl) triphenylamine (TCTA), and/or the like, and/or may include epoxy resins and/or acrylates such as methacrylates.

The emission layer EML may include a fluorescent material and/or a phosphorescent material. For example, the emission layer EML may include an anthracene derivative, a pyrene derivative, a fluoranthene derivative, a chrysene derivative, a dihydrobenzanthracene derivative, and/or a triphenylene derivative. In embodiments, the emission layer EML may include a metal organic complex as a light emitting material.

The pixel defining film PDL included in the display panel DP may be an organic layer. A light emitting opening OH is defined in the pixel defining film PDL. The light emitting opening OH of the pixel defining film PDL allows at least a portion of the first electrode AE to be exposed. In an embodiment, light emitting region EA1, EA2, and EA3 may be defined by the light emitting opening OH.

The pixel defining film PDL may be formed of a polymer resin. For example, the pixel defining film PDL may be formed including a polyacrylate-based resin and/or a polyimide-based resin. In embodiments, the pixel defining film PDL may be formed by further including an inorganic material in addition to the polymer resin. In embodiments, the pixel defining film PDL may be formed including a light absorbing material, and/or may be formed including a black pigment and/or a black dye. The pixel defining films PDL formed including a black pigment and/or a black dye may implement a black pixel defining film. When forming the pixel defining film PDL, carbon black may be used as a black pigment and/or a black dye, but embodiments of the present disclosure are not limited thereto.

In embodiments, the pixel defining film PDL may be formed of an inorganic material. For example, the pixel defining film PDL may be formed of an inorganic material such as silicon nitride (SiNₓ), silicon oxide (SiOₓ), and/or silicon nitride (SiOₓN_{y}).

The light emitting opening OP of the pixel defining film PDL may expose at least a portion of the first electrode AE. On a plane, the pixel defining film PDL may overlap the peripheral region NPXA and may non-overlap the pixel regions PXA-R, PXA-G, and PXA-B. In embodiments, the fact that two components “overlap” is not limited to having the same area and the same shape on a plane, and also includes cases where the two components have different areas and/or different shapes.

The display element layer DP-ED may include a first light emitting region EA1, a second light emitting region EA2, and a third light emitting region EA3. The first light emitting region EA1, the second light emitting region EA2, and the third light emitting region EA3 may be regions divided by the pixel defining film PDL. The first light emitting region EA1, the second light emitting region EA2, and the third light emitting region EA3 may respectively correspond to the first pixel region PXA-R, the second pixel region PXA-G, and the third pixel region PXA-B. The first light emitting region EA1, the second light emitting region EA2, and the third light emitting region EA3 may be referred to as a red light emitting region, a green light emitting region, and a blue light emitting region, respectively. In an embodiment, the pixel regions PXA-R, PXA-G, and PXA-B may be regions divided by color filters CF-R, CF-G, and CF-B.

The first pixel region PXA-R may be a region corresponding to the first light emitting region EA1 and a first light control portion CCP1, the second pixel region PXA-G may be a region corresponding to the second light emitting region EA2 and a second light control portion CCP2, and the third pixel region PXA-B may be a region corresponding to the third light emitting region EA3 and a third light control portion CCP3. In an electronic device of an embodiment, the first pixel region PXA-R, the second pixel region PXA-G, and the third pixel region PXA-B emitting light of different wavelength ranges may be sequentially provided in the first direction DR1. As used herein, the term “correspond” indicates that two components overlap when viewed in the thickness direction DR3 of the electronic device ED (FIG. 1), and is not limited to the two components having the same area.

The display element layer DP-ED may include an encapsulation layer TFE that protects the light emitting element LED. The encapsulation layer TFE may cover the light emitting element LED. The encapsulation layer TFE may be a thin film encapsulation layer. The encapsulation layer TFE may include an organic material and/or an inorganic material. The encapsulation layer TFE may have a multilayer structure in which an inorganic layer and an organic layer are repeated (e.g., alternated).

In an embodiment, the encapsulation layer TFE may include a first inorganic layer IOL1, an organic layer OL, and a second inorganic layer IOL2, which are sequentially stacked. However, the layers constituting the encapsulation layer TFE are not limited thereto. The encapsulation layer TFE be directly provided on the light emitting element LED through a roll-to-roll process.

The first inorganic layer IOL1 and the second inorganic layer IOL2 may protect the light emitting element LED against moisture and oxygen, and the organic layer OL may protect the light emitting element LED against foreign substances such as dust particles. For example, the organic layer OL may prevent or reduce dent defects on the light emitting element LED caused by foreign substances introduced during the manufacturing process. In embodiments, the display panel DP may further include a refractive index control layer on an upper side of the encapsulation layer TFE to increase light output efficiency.

The inorganic layers IOL1 and IOL2 may include at least one of silicon nitride, silicon oxynitride, silicon oxide, titanium oxide, or aluminum oxide. The organic layer OL may include an acryl-based organic material. However, the types or kinds of materials constituting the inorganic layers IOL1 and IOL2 and the organic layer OL are not limited thereto.

In the display module DM according to an embodiment, the light control panel OPN may be on the display panel DP. The light control panel OPN may be on the encapsulation layer TFE.

The light control panel OPN may include a light control layer CCL including a light converter. For example, the light control layer CCL may include a quantum dot as a light converter. Embodiments of the present disclosure are not limited thereto, and the light control layer CCL may also include a phosphor as a light converter. In an embodiment, the light control layer CCL may be on the encapsulation layer TFE. The light control panel OPN may include color filter layers CFL and CFL-1 on the light control layer CCL.

The light control layer CCL may include a division pattern BK and a plurality of light control portions CCP1, CCP2, and CCP3. In embodiments, the light control layer CCL may further include at least one of a first barrier layer BFL1 or a second barrier layer BFL2.

The division pattern BK may be configured to distinguish between a plurality of light control portions CCP1, CCP2, and CCP3. The division pattern BK may include a base resin and an additive. The base resin may be formed of various suitable resin compositions, which may be generally referred to as a binder. The additive may include a coupling agent and/or a photo-initiator. The additive may further include a dispersant.

The division pattern BK may include a black component for light blocking. The division pattern BK may include a black dye and a black pigment mixed with a base resin. In an embodiment, the black component may include carbon black, a metal such as chromium, and/or an oxide thereof.

The light control layer CCL may include a plurality of light control portions CCP1, CCP2, and CCP3. In an embodiment, the light control layer CCL may include a first light control portion CCP1 corresponding to the first pixel region PXA-R, a second light control portion CCP2 corresponding to the second pixel region PXA-G, and a third light control portion CCP3 corresponding to the third pixel region PXA-B. The first light control portion CCP1 may be a red light control portion that emits red light, and the second light control portion CCP2 may be a green light control portion that emits green light. The third light control portion CCP3 may be a blue light control portion that emits blue light. In embodiments, the third light control portion CCP3 may be a transmission light control portion that transmits and emits source light. At least one of the first to third light control portions CCP1, CCP2, and CCP3 of the light control layer CCL may include a quantum dot that converts an optical property of source light provided from the light emitting element LED.

The first light control portion CCP1 may include a first quantum dot that converts source light into light of a different wavelength. In embodiments, the second light control portion CCP2 may include a second quantum dot that converts source light into light of a different wavelength. In an embodiment, the first quantum dot may convert source light into red light, and the second quantum dot may convert source light into green light. In an embodiment, the first quantum dot may be a red quantum dot, and the second quantum dot may be a green quantum dot.

In embodiments, a quantum dot indicates a crystal of a semiconductor compound. The quantum dot may emit light of various suitable light emitting wavelengths depending on the size of the crystal. The quantum dot may emit light of various suitable light emitting wavelengths by regulating an element ratio in a semiconductor compound.

The quantum dot may have a diameter of, for example, about 1 nm to about 10 nm. The quantum dot may be synthesized through a wet chemical process, a metal organic chemical vapor deposition process, a molecular beam epitaxy process, and/or a process similar thereto.

Among the quantum dot manufacturing processes, the wet chemical process is a method of mixing an organic solvent and a precursor material and then growing a quantum dot particle crystal. When the quantum dot particle crystal grows, an organic solvent naturally serves as a dispersant coordinated to a surface of the quantum dot crystal and may control the growth of the particle crystal. Therefore, the wet chemical process is easier than vapor deposition methods such as metal organic chemical vapor deposition or molecular beam epitaxy, and may control the growth of quantum dot particles through a low-cost process.

A core of the quantum dot may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In embodiments, the Group II-VI semiconductor compound may further include a Group I metal and/or a Group IV element. The Group I-II-VI compound may be selected from CuZnS, and the Group II-IV-VI compound may be selected from ZnSnS and the like. The Group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, or a mixture thereof, or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. Meanwhile, the Group III-V compound may further include a Group II metal. For example, InZnP and the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V semiconductor compound may be a ternary compound selected from the group consisting of ZnSnP, ZnSnP₂, ZnSnAs₂, ZnGeP₂, ZnGeAs₂, CdSnP₂, CdGeP₂ and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particles at a uniform (e.g., substantially uniform) concentration or a non-uniform concentration. For example, a formula representing quantum dots indicates the types or kinds of elements included in a quantum dot compound, and element ratios in the compound may be different.

In embodiments, the binary compound, the ternary compound, and/or the quaternary compound may be present in particles having a uniform (e.g., substantially uniform) concentration distribution, or may be present in the same particles having a partially different concentration distribution. In embodiments, a core/shell structure in which one quantum dot surrounds another quantum dot may be present. The core/shell structure may have a concentration gradient in which the concentration of an element present in the shell becomes lower along a direction towards the core.

In some embodiments, the quantum dots may have the above-described core/shell structure including a core having nano-crystals and a shell surrounding the core. The shell of the quantum dots may serve as a protection layer to prevent or reduce chemical deformation of the core so as to maintain semiconductor properties, and/or a charging layer to impart electrophoresis properties to the quantum dots. The shell may be a single layer or a plurality of layers. Examples of the shell of the quantum dot may be a metal and/or non-metal oxide, a semiconductor compound, or a combination thereof.

For example, the metal and/or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or a ternary compound such as MgAl₂O₄, CoFe₂O₄, NiFe₂O₄, and/or CoMn₂O₄, but embodiments of the present disclosure are not limited thereto.

In embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb, but embodiments of the present disclosure are not limited thereto.

For example, when a quantum dot of a Group III-V compound has a core/shell structure, the core may include InP or InZnP, and the shell may include ZnSeS or have a double-shell structure of ZnSe/ZnS. However, embodiments of the present disclosure are not limited thereto, and the quantum dot may have a combination of core and shell selected from the semiconductor compounds described above.

The quantum dot may exhibit an emission wavelength spectrum having a full width at half maximum (FWHM) of about 45 nm or less, about 40 nm or less, or about 30 nm or less, and in this range, the color purity and/or the color reproducibility may be improved. In embodiments, light emitted through the quantum dot is emitted in all (e.g., substantially all) directions, and thus a wide viewing angle may be improved.

In embodiments, the form of the quantum dots is not particularly limited as long as it is a form generally used in the art, but, for example, a quantum dot in the form of spherical, pyramidal, multi-arm, and/or cubic nanoparticles, nanotubes, nanowires, nanofibers, nanoplatelets, and/or the like may be used.

As the size of the quantum dot or the ratio of elements in the quantum dot compound is regulated, the energy band gap may be accordingly controlled to obtain light of various suitable wavelengths from a quantum dot emission layer. Therefore, by using the quantum dot as described above (using quantum dots of different sizes or having different element ratios in the quantum dot compound), a light emitting element emitting light of various suitable wavelengths may be obtained. For example, the size of the quantum dot or the ratio of elements in the quantum dot compound may be regulated to emit red, green, and/or blue light. In embodiments, quantum dots may be configured to emit white light through a combination of light of various suitable colors.

In an embodiment, the smaller the particle size of the quantum dot becomes, light in the short wavelength range may be emitted. For example, in quantum dots having the same core, the particle size of a quantum dot that emits green light may be smaller than the particle size of a quantum dot that emits red light. In embodiments, in quantum dots having the same core, the particle size of a quantum dot that emits blue light may be smaller than the particle size of a quantum dot that emits green light. However, embodiments of the present disclosure are not limited thereto, and even in quantum dots having the same core, the particle size may be controlled according to a shell forming material and a shell thickness.

In embodiments, when the quantum dots have various suitable light emission colors such as blue, red, and green, the quantum dots having different light emission colors may have different core materials.

The first light control portion CCP1 may correspond to the first pixel region PXA-R, the second light control portion CCP2 may correspond to the second pixel region PXA-G, and the third light control portion CCP3 may correspond to the third pixel region PXA-B.

In an embodiment, the first light control portion CCP1 may include red quantum dots, and the second light control portion CCP2 may include green quantum dots. The first light control portion CCP1, the second light control portion CCP2, and the third light control portion CCP3 may include a base resin. In embodiments, the first light control portion CCP1, the second light control portion CCP2, and the third light control portion CCP3 may each further include a scatterer (e.g., a light scatterer).

In an embodiment, the third light control portion CCP3 may not include quantum dots. However, embodiments of the present disclosure are not limited thereto, and the third light control portion CCP3 may further include quantum dots that are wavelength-converted into light of a different wavelength range from the first and second light control portions.

In an embodiment, the scatterer may cause light incident on the light control portions CCP1, CCP2, and CCP3 to be uniformly (e.g., substantially uniformly) scattered and emitted. The scatterer may scatter and emit source light, or scatter and emit light that is wavelength-converted from source light.

The scatterer may have a spherical shape having a diameter of several tens to several hundreds of nanometers. For example, in an embodiment, the scatterer may have a diameter of about 50 nm to about 300 nm. In an embodiment, the scatterer may have a diameter of about 200 nm.

The scatterer may include inorganic particles. For example, the scatterer may include TiO₂, BaTiO₃, ZnO, ZnS, Al₂O₃, SiO₂, and/or hollow silica.

The base resin may be a medium in which the quantum dots and the scatterers are dispersed, and may be formed of various suitable compositions which may be generally referred to as a binder. For example, the base resin may be an acrylate-based resin portion, a urethane-based resin portion, a silicone-based resin portion, and/or an epoxy-based resin portion. The base resin included in the first to third light control portions CCP1, CCP2, and CCP3 may all be the same, or a base resin portion of at least one light control portion may be different from a base resin portion of the other light control portions.

The light control layer CCL may include barrier layers BFL1 and BFL2. The barrier layers BFL1 and BFL2 may serve to prevent or reduce penetration of moisture and/or oxygen (hereinafter, referred to as ‘moisture/oxygen’) and improve optical properties of the light control layer CCL by regulating a refractive index. The barrier layers BFL1 and BFL2 may be on an upper portion or a lower portion of the light control portions CCP1, CCP2, and CCP3. The barrier layers BFL1 and BFL2 may be on the upper or lower surface of the light control portions CCP1, CCP2, and CCP3 to prevent or reduce exposure of the light control portions CCP1, CCP2, and CCP3 to moisture/oxygen, and for example, may prevent or reduce exposure of quantum dots included in the light control portions CCP1, CCP2, and CCP3 to moisture/oxygen. The barrier layers BFL1 and BFL2 may also protect the light control portions CCP1, CCP2, and CCP3 from external shock.

In an embodiment, the first barrier layer BFL1 may be between the light control portions CCP1, CCP2, and CCP3 and the display element layer DP-ED. The first barrier layer BFL1 may cover the lower surface of the light control portions CCP1, CCP2, and CCP3 adjacent to the display element layer DP-ED. The second barrier layer BFL2 may be spaced apart from the display element layer DP-ED with the light control portions CCP1, CCP2, and CCP3 therebetween. For example, the first barrier layer BFL1 may be on the upper surface of the light control portions CCP1, CCP2, and CCP3. As described herein, the “upper surface” may be a surface placed on an upper portion with respect to the third direction DR3, and the “lower surface” may be a surface placed on a lower portion with respect to the third direction DR3.

In embodiments, the first barrier layer BFL1 and the second barrier layer BFL2 may cover the light control portions CCP1, CCP2, and CCP3 and one surface of the division pattern BK.

The first barrier layer BFL1 and the second barrier layer BFL2 may be formed including an inorganic material. For example, the first barrier layer BFL1 and the second barrier layer BFL2 may each be formed including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film in which light transmittance is secured, and/or the like. The first barrier layer BFL1 and the second barrier layer BFL2 may include silicon oxynitride, but embodiments of the present disclosure are not limited thereto.

The light control panel OPN may include color filter layers CFL and CFL-1 on the light control layer CCL. For example, the color filter layers CFL and CFL-1 may be directly on the light control layer CCL. In embodiments, the first barrier layer BFL1 may not be provided.

The color filter layers CFL and CFL-1 includes at least one of the color filters CF-R, CF-G, or CF-B. The color filter layers CFL and CFL-1 may include a plurality of color filters CF-R, CF-G, and CF-B. The color filters CF-R, CF-G, and CF-B transmit light having a set or specific wavelength range and block light having a wavelength other than the set or specific wavelength range. The color filters CF-R, CF-G, and CF-B may transmit either red light, green light, or blue light. In an embodiment, the first color filter CF-R may be a red filter that transmits red light, the second color filter CF-G may be a green filter that transmits green light, and the third color filter CF-B may be a blue filter that transmits blue light.

Each of the color filters CF-R, CF-G, and CF-B includes a polymer photosensitive resin, a photo-initiator, and a colorant. The photo-initiator may include a nucleophilic substance. The photo-initiator may include Cl−, an amine group, and/or the like as a nucleophilic substance. For example, the color filters CF-R, CF-G, and CF-B may use a substance including an amine group as a photo-initiator, but embodiments of the present disclosure are not limited thereto. The photo-initiator may include a free radical photo-initiator. For example, the free radical photo-initiator may be an oxime ester type such as IRGACURE® Oxe02 of Formula 1 below and Optomer N 1919 of Formula 2 below; an α-aminoketone type, a benzophenone type, a benzildimethyl ketal type, and/or the like, but is not limited to any one embodiment.

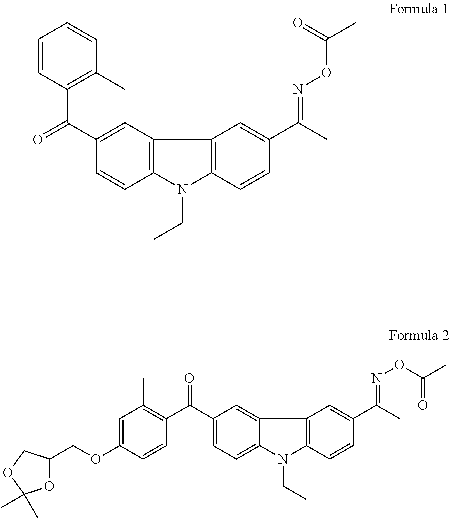

The colorant may include pigments and/or dyes. The first color filter CF-R may include a red pigment and/or a red dye. The second color filter CF-G may include a green pigment and/or a green dye, and the third color filter CF-B may include a blue pigment and/or a blue dye. In some embodiments, the third color filter B may not include pigments or dyes.

In an embodiment, the colorant included in the second color filter CF-G may exhibit an emission wavelength spectrum having a full width at half maximum (FWHM) of about 70 nm or less or 50 nm or less. The colorant included in the second color filter CF-G may exhibit an emission wavelength spectrum having a full width at half maximum (FWHM) of about 100 nm or less or 80 nm or less. The colorants having a full width at half maximum in the above range may improve color purity and/or color reproducibility. In the display module DM of an embodiment, when the colorants included in the color filters CF-R, CF-G, and CF-B have a small full width at half maximum, the absorption wavelength range of the color filters CF-R, CF-G, and CF-B may increase, and the content of colorants and photo-initiator in the color filters CF-R, CF-G, and CF-B may increase.

The first to third color filters CF-R, CF-G, and CF-B may be provided to correspond to the first pixel region PXA-R, the second pixel region PXA-G, and the third pixel region PXA-B, respectively. The first to third color filters CF-R, CF-G, and CF-B may be provided to correspond to the first light emitting region EA1, the second light emitting region EA2, and the third light emitting region EA3, respectively. In embodiments, the first to third color filters CF-R, CF-G, and CF-B may be provided to correspond to the first to third light control portions CCP1, CCP2, and CCP3, respectively.

In the color filter layer CFL of an embodiment of illustrated in FIG. 6A, a plurality of color filters CF-R, CF-G, and CF-B that transmit different types or kinds of light may be provided to overlap, corresponding to the peripheral region NPXA. In the peripheral region NPXA, the plurality of color filters CF-R, CF-G, and CF-B may be provided to overlap in the third direction DR3, which is a thickness direction, to separate borders between the adjacent pixel regions PXA-R, PXA-G, and PXA-B. Accordingly, the effect of blocking external light increases to serve as the same function as a black matrix. The overlapping structure of the plurality of color filters CF-R, CF-G, and CF-B may serve to prevent or reduce color mixing.

The display module DM of an embodiment shown in FIG. 6B differs from the display module DM illustrated in FIG. 6A, in the configuration of the color filter layer CFL-1 included in the light control panel OPN.

Referring to FIG. 6B, the color filter layer CFL-1 of an embodiment may include a plurality of color filters CF-R, CF-G, and CF-B, and a light blocking portion BM. The light blocking portion BM may overlap the peripheral region NPXA and may non-overlap the pixel regions PXA-R, PXA-G, and PXA-B. The light blocking portion BM may be formed of a blue filter or may include an organic light blocking material and/or an inorganic light blocking material that includes a black pigment and/or a black dye.

In embodiments, in the color filter layer CFL-1 of an embodiment shown in FIG. 6B, the first to third filters CF-R, CF-G, and CF-B may be separated by the light blocking portion BM and may non-overlap one another. The light blocking portion BM may be a black matrix. The light blocking portion BM may be formed including an organic light blocking material and/or an inorganic light blocking material, both including a black pigment and/or a black dye. The light blocking portion BM may prevent or reduce light leakage, and separate borders between the adjacent color filters CF-R, CF-G, and CF-B.

Referring back to FIGS. 6A and 6B, an overcoat layer OPL may be on the color filter layers CFL and CFL-1. The overcoat layer OPL may include at least one organic layer and at least one inorganic layer. In an embodiment, at least one organic layer in the overcoat layer OPL may include an organic material exhibiting high strength and high planarization properties. Consequently, the overcoat layer OPL may provide a flat upper surface. In embodiments, at least one inorganic layer in the overcoat layer OPL of an embodiment may block the penetration of moisture and/or oxygen (hereinafter referred to as ‘moisture/oxygen’). The inorganic layer included in the overcoat layer OPL may block the color filters CF-R, CF-G, and CF-B from being exposed to moisture/oxygen.

An anti-reflection layer ARL may be on the overcoat layer OPL. The anti-reflection layer ARL may be directly on the overcoat layer OPL. For example, the anti-reflection layer ARL may be in contact with the upper surface of the overcoat layer OPL. The anti-reflection layer ARL may be a layer that has a low reflectivity and thus blocks external light. The anti-reflection layer ARL may be a layer that has a plurality of layers with different refractive indices and thus effectively blocks external light through destructive interference. The anti-reflection layer ARL may have a reflectance of about 2% or less on an upper surface thereof. In a visible light range of about 430 nm to about 780 nm, the anti-reflection layer ARL may have a reflectance of about 2% or less on the upper surface thereof. The anti-reflection layer ARL may have a reflectance of about 2% or less on an upper surface thereof at a wavelength of about 550 nm.

The light control panel OPN may further include a low refractive layer LR between the light control layer CCL and the color filter layers CFL and CFL-1. The low refractive layer LR may be directly on the second barrier layer BFL2, and the color filter layer CFL may be directly on the low refractive layer LR.

The low refractive layer LR may be on an upper portion of the light control layer CCL to prevent or reduce exposure of the light control portions CCP1, CCP2, and CCP3 to moisture/oxygen. In embodiments, the low refractive layer LR may serve as a light functional layer that is between the light control portions CCP1, CCP2, and CCP3 and the color filters CF-R, CF-G, and CF-B to increase light extraction efficiency or prevent or reduce incidence of reflected light on the light control layer CCL. The low refractive layer LR may have a smaller refractive index than a layer adjacent thereto.

The low refractive layer LR may include at least one inorganic layer. For example, the low refractive layer LR may be formed including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film in which light transmittance and/or the like is secured. However, embodiments of the present disclosure are not limited thereto, and the low refractive layer LR may include an organic layer. The low refractive layer LR may have, for example, a structure in which a plurality of hollow particles are dispersed in an organic polymer resin. The low refractive layer LR may be formed of a single layer or a plurality of layers.

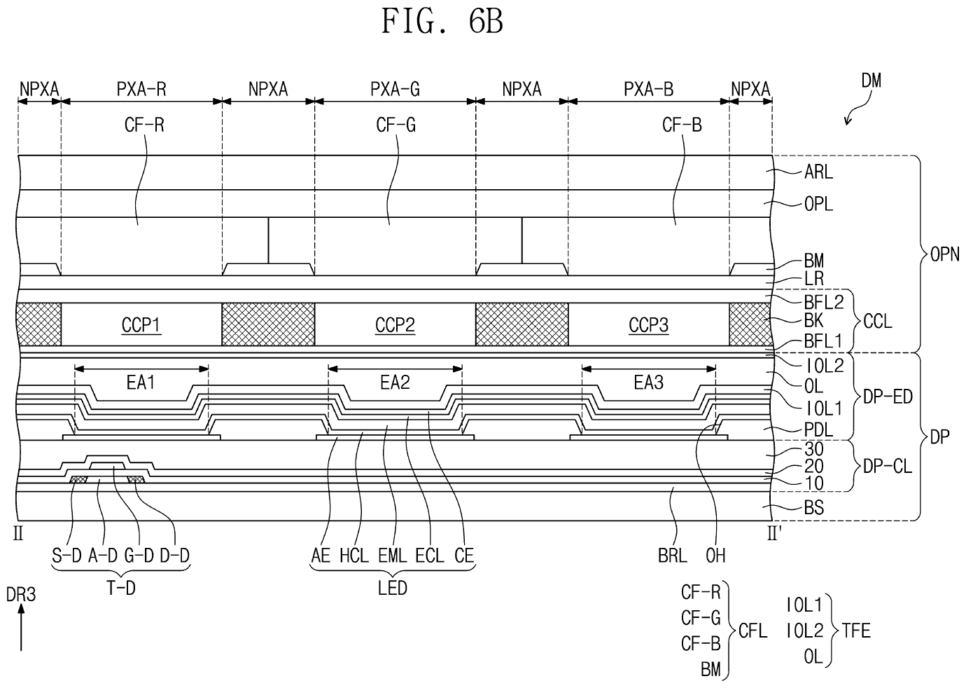

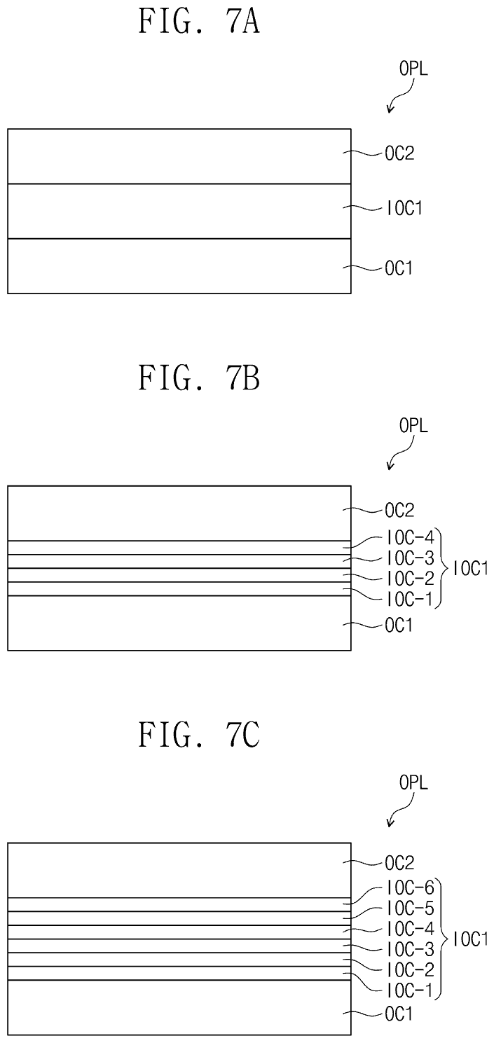

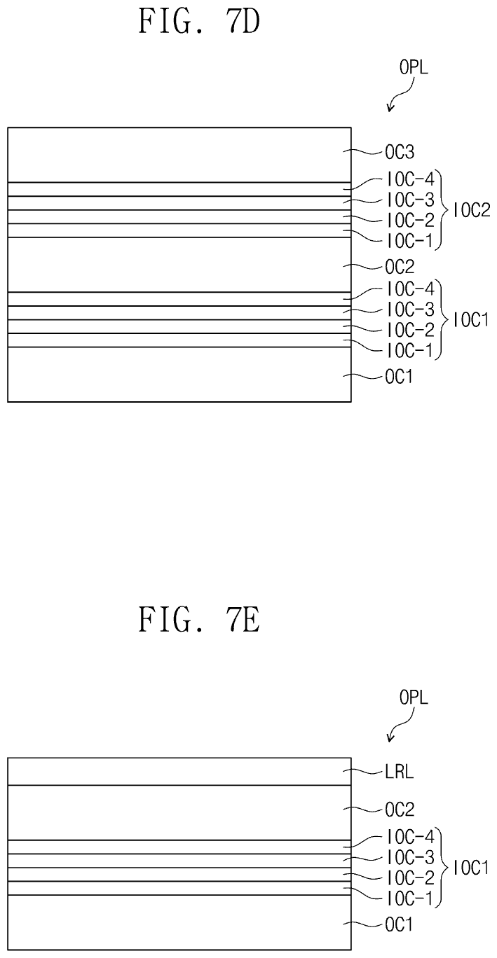

FIGS. 7A to 7E are each cross-sectional views schematically showing an overcoat layer of an embodiment. The overcoat layer OPL may include at least one organic layer and at least one inorganic layer. The overcoat layer OPL may include two organic layers facing each other and one inorganic layer between the two organic layers. Embodiments of the present disclosure are not limited thereto, and the overcoat layer OPL may further include each of the organic layer and the inorganic layer. In an embodiment, the overcoat layer OPL includes a first organic overcoat layer OC1, a second organic overcoat layer OC2, and a first inorganic overcoat layer IOC1. The overcoat layer OPL may further include a third organic overcoat layer OC3 and a second inorganic overcoat layer IOC2. The organic overcoat layers OC1, OC2, and OC3 may correspond to the organic layer of the overcoat layer OPL, and the inorganic overcoat layers IOC1 and IOC2 may correspond to the inorganic layer of the overcoat layer OPL.

FIG. 7B, compared to FIG. 7A, is a cross-sectional view showing an overcoat layer OPL of an embodiment, in which the first inorganic overcoat layer IOC1 includes a plurality of inorganic films IOC-1, IOC-2, IOC-3, and IOC-4. FIG. 7C, compared to FIG. 7B, is a cross-sectional view showing an overcoat layer OPL of an embodiment, in which the first inorganic overcoat layer IOC1 includes a plurality of inorganic films IOC-1, IOC-2, IOC-3, IOC-4, IOC-5, and IOC-6. FIG. 7D, compared to FIG. 7A, is a cross-sectional view showing an overcoat layer OPL of an embodiment, in which the first inorganic overcoat layer OC3 and the second inorganic overcoat layer IOC2 are further included, and each of the first and second inorganic overcoat layers IOC1 and IOC2 includes a plurality of inorganic films IOC-1, IOC-2, IOC-3, and IOC-4. FIG. 7E, compared to FIG. 7B, is a cross-sectional view showing an overcoat layer OPL of an embodiment, including a low refractive index layer LRL on the second organic overcoat layer OC2.

The organic overcoat layers OC1, OC2, and OC3 may each have a thickness of about 0.5 μm to about 20 μm. For example, the organic overcoat layers OC1, OC2, and OC3 may each have a thickness of about 5 μm to about 15 μm.

The organic overcoat layers OC1, OC2, and OC3 may be formed from a resin composition for forming an overcoat (hereinafter, “resin composition”) including a base resin and a polyol compound. The organic overcoat layers OC1, OC2, and OC3 may include a polymer derived from a resin composition including a base resin and a polyol compound. The base resin may include at least one of a polysilsesquioxane compound or a polysiloxane compound. The polysilsesquioxane compound and the polysiloxane compound may each include epoxide in molecules. In an embodiment, the base resin may include a polysilsesquioxane (PSSQ) compound. For example, the polysilsesquioxane compound may be represented by Formula 3 below, but embodiments of the present disclosure are not limited thereto.

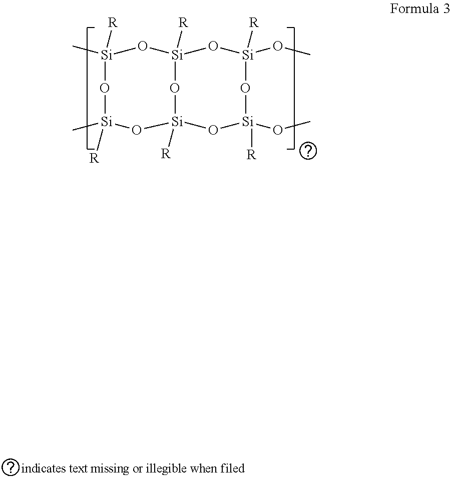

In Formula 3 above, R may each independently be

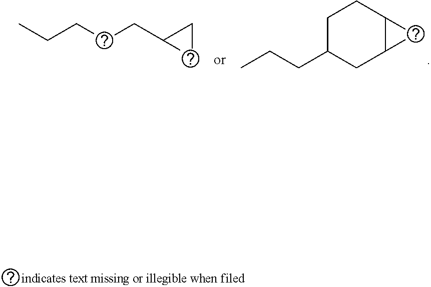

In embodiments, n may range from about 1 to 10,000.

In embodiments where the resin composition of an embodiment includes a polysilsesquioxane compound as a base resin, the polysilsesquioxane compound may be provided in an amount of about 50 wt % or less with respect to a total weight of the resin composition. For example, the polysilsesquioxane compound may be provided in an amount of about 30 wt % to about 50 wt %, or about 30 wt % to about 40 wt %, with respect to 100 wt % of the total resin composition.

The polyol compound may include at least one of a diol compound or a triol compound. For example, the polyol compound may be polycaprolactone triol, polyether polyol, and/or the like, and may be represented by the following formula structure, but embodiments of the present disclosure are not limited thereto.

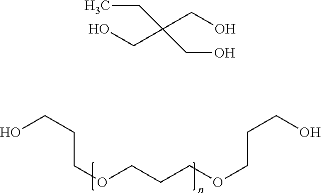

When the polyol compound is included in the resin composition of an embodiment, the polyol compound may be provided in an amount of about 10 wt % or less with respect to a total weight of the resin composition. For example, the polyol compound may be provided in an amount of greater than 0 and 10 wt % or less, or greater than 0 and 1 wt % or less, with respect to 100 wt % of the total resin composition.

In embodiments, when the resin composition does not include a polyol compound when forming an organic overcoat layer, but only includes a base resin such as a polysilsesquioxane compound, a nucleophilic substance such as an amine component of a photo-initiator may be eluted from a color filter layer during the process of forming an organic overcoat layer on the color filter layer, thereby inhibiting or reducing the polymerization reaction of an organic overcoat layer forming material. For example, the organic overcoat layer may exhibit degradation in curing degree due to H⁺ depletion by a nucleophilic substance such as Cl − and/or amine.

The resin composition of an embodiment includes a polyol compound along with a base resin such as a polysilsesquioxane compound, thereby suppressing or reducing the degradation in curing degree caused by a nucleophilic substance when forming organic overcoat layers OC1, OC2, and OC3 on the color filter layers CFL and CFL-1 (FIGS. 6A and 6B). For example, the polyol compound included in the resin composition may react with the epoxide included in the polysilsesquioxane compound to form a crosslink, releasing new protons (H⁺) to enable further polymerization. For example, the epoxide and the polyol may react as follows to form a crosslink, but embodiments of the present disclosure are not limited thereto.

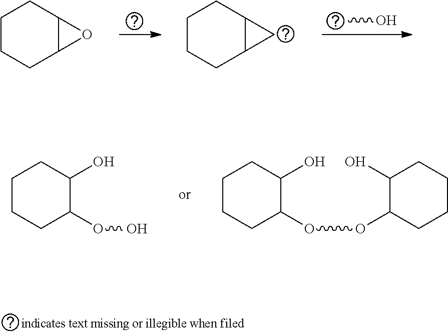

The resin composition of an embodiment includes a base resin such as a polysilsesquioxane compound and a polyol compound, and may thus increase crosslinking density when forming organic overcoat layers OC1, OC2, and OC3, thereby improving the robustness of the organic overcoat layers OC1, OC2, and OC3.

The resin composition may include a photo-initiator. The photo-initiator may be a cationic photo-initiator. For example, the cationic photo-initiator may be dialkylphenacylsulfonium salt, dialkyl1-4-hydroxyphenylsulfonium salt, and/or the like (salt: BF₄_{^{−}}, PF₆_{^{−}}, AsF₆_{^{−}}, SbF₆_{^{−}}), but embodiments of the present disclosure are not limited thereto.

The resin composition may further include at least one of an additive or a solvent. The additive may be a leveling agent, a sensitizer, and/or the like. The solvent may include EDM, PGMEA, and/or the like.

Referring to FIG. 7A and FIGS. 6A and 6B together, in the overcoat layer OPL of an embodiment, the first organic overcoat layer OC1 may be provided adjacent to the color filter layers CFL and CFL-1. The first organic overcoat layer OC1 may be directly on the color filter layers CFL and CFL-1. The first organic overcoat layer OC1 may cover the first to third color filters CF-R, CF-G, and CF-B and the light blocking portion BM. The first organic overcoat layer OC1 may be in direct contact with the first to third color filters CF-R, CF-G, and CF-B. The first organic overcoat layer OC1 of an embodiment is formed from the resin composition of an embodiment including a base resin such as a polysilsesquioxane compound, and a polyol compound, thus ensuring no (or substantially no) degradation in curing degree, resulting in superior robustness and flatness.

The second organic overcoat layer OC2 may face the first organic overcoat layer OC1. The second organic overcoat layer OC2 may be spaced apart from the first organic overcoat layer OC1 with the first inorganic overcoat layer IOC1 therebetween. For example, the first organic overcoat layer OC1, the first inorganic overcoat layer IOC1, and the second organic overcoat layer OC2 may be sequentially provided in the thickness direction. The second organic overcoat layer OC2 is also formed from the resin composition of an embodiment described above, and may thus provide superior robustness and also protect lower substrates from external impact.

The first inorganic overcoat layer IOC1 may be between the first organic overcoat layer OC1 and the second organic overcoat layer OC2. The first inorganic overcoat layer IOC1 may include at least one of silicon oxide (SiOₓ) or silicon nitride (SiNₓ). The first inorganic overcoat layer IOC1 may be a single layer or a multilayer. The first inorganic overcoat layer IOC1 may be a single layer including silicon oxide (SiOₓ) or silicon nitride (SiNₓ). The first inorganic overcoat layer IOC1 may have a multilayer structure in which an inorganic film including either silicon oxide (SiOₓ) or silicon nitride (SiNₓ) is stacked in the thickness direction. The first inorganic overcoat layer IOC1 of an embodiment is between the organic overcoat layers OC1 and OC2 to prevent or reduce penetration of moisture and/or impurities into lower substrates such as the color filters CF-R, CF-G, and CF-B or the light control layer CCL.

The first inorganic overcoat layer IOC1 may include at least one of a first inorganic film including silicon oxide or a second inorganic film including silicon nitride. The first inorganic overcoat layer IOC1 may include only the first inorganic film including silicon oxide, or may include only the second inorganic film including silicon nitride. In embodiments, the first inorganic overcoat layer IOC1 may include at least one first inorganic film including silicon oxide, and may include at least one second inorganic film including silicon nitride.

In an embodiment, the first inorganic overcoat layer IOC1 may include a plurality of first inorganic films and a plurality of second inorganic films. The first inorganic overcoat layer IOC1 of an embodiment may have a multilayer structure formed by the first inorganic film and the second inorganic film alternately stacked. In embodiments, the first inorganic overcoat layer IOC1 may include only a plurality of first inorganic films, or may include only a plurality of second inorganic films. The first inorganic overcoat layer IOC1 having a multilayer structure may provide superior properties of preventing or reducing moisture permeation.

In the overcoat layer OPL of an embodiment, the first inorganic overcoat layer IOC1 may include a plurality of inorganic films IOC-1, IOC-2, IOC-3, and IOC-4 stacked in the thickness direction on the first organic overcoat layer OC1. In FIG. 7B, the first inorganic overcoat layer IOC1 is shown as including four inorganic films IOC-1, IOC-2, IOC-3, and IOC-4.

Referring to FIG. 7B, as for the first inorganic overcoat layer IOC1 of an embodiment, a plurality of inorganic films IOC-1, IOC-2, IOC-3, and IOC-4 stacked in the thickness direction, inorganic films including different inorganic materials may be alternately stacked. For example, the first inorganic overcoat layer IOC1 may include a first inorganic film IOC-1 including silicon oxide, a second inorganic film IOC-2 including silicon nitride, a third inorganic film IOC-3 including silicon oxide, and a fourth inorganic film IOC-4 including silicon nitride, which are sequentially stacked on the first organic overcoat layer OC1.

Referring to FIG. 7C, the first inorganic overcoat layer IOC1 may further include a fifth inorganic film IOC-5 and a sixth inorganic film IOC-6 to improve properties of preventing or reducing moisture permeation. The fifth inorganic layer IOC-5 and the sixth inorganic layer IOC-6 may each include at least one of silicon oxide (SiOₓ) or silicon nitride (SiNₓ). For example, the fifth inorganic film IOC-5 may include silicon oxide, and the sixth inorganic film IOC-6 may include silicon nitride, but embodiments of the present disclosure are not limited thereto. In FIG. 7C, the first inorganic overcoat layer IOC1 is shown as including six inorganic films IOC-1, IOC-2, IOC-3, IOC-4, IOC-5, and IOC-6, but embodiments of the present disclosure are not limited thereto, and the first inorganic overcoat layer IOC1 may include n or more inorganic films, where n is a natural number greater than or equal to 7.

Referring to FIG. 7D, the overcoat layer OPL of an embodiment may include first to third organic overcoat layers OC1, OC2, and OC3, and may include first and second inorganic overcoat layers IOC1 and IOC2. The first to third organic overcoat layers OC1, OC2, and OC3 are each formed from the resin composition of an embodiment including a base resin such as a polysilsesquioxane compound, and a polyol compound, and may thus exhibit superior robustness and protect lower substrates from external impact.

In the overcoat layer OPL of an embodiment shown in FIG. 7B, a first inorganic overcoat layer IOC1 may be between a first organic overcoat layer OC1 and a second organic overcoat layer OC2, and a second inorganic overcoat layer IOC2 may be between a second organic overcoat layer OC2 and a third organic overcoat layer OC3. The overcoat layer OPL of an embodiment may include inorganic overcoat layers IOC1 and IOC2 between the organic overcoat layers OC1, OC2, and OC3 to protect lower substrates from external moisture and oxygen.

The first and second inorganic overcoat layers IOC1 and IOC2 may each include at least one of silicon oxide (SiOₓ) or silicon nitride (SiNₓ). The first and second inorganic overcoat layers IOC1 and IOC2 may each include a plurality of inorganic films IOC-1, IOC-2, IOC-3, and IOC-4. The plurality of inorganic films IOC-1, IOC-2, IOC-3, and IOC-4 may each include at least one of silicon oxide (SiOₓ) or silicon nitride (SiNₓ). The inorganic films included in the first inorganic overcoat layer IOC1 and the second inorganic overcoat layer IOC2 may be the same as or different from each other. For example, the first and second inorganic overcoat layers IOC1 and IOC2 may each include a first inorganic film IOC-1 including silicon oxide, a second inorganic film IOC-2 including silicon nitride, a third inorganic film IOC-3 including silicon oxide, and a fourth inorganic film IOC-4 including silicon nitride, which are sequentially stacked in the thickness direction, but embodiments of the present disclosure are not limited thereto.

Referring to FIG. 7E, the overcoat layer OPL of an embodiment may further include a low refractive index layer LRL. The low refractive index layer LRL may be on the second organic overcoat layer OC2. When the overcoat layer OPL includes a third organic overcoat layer OC3 (FIG. 7D), the low refractive index layer LRL may be on the third organic overcoat layer OC3. The low refractive index layer LRL may be a layer that controls surface treatment or reflective properties. The low refractive index layer LRL may have a smaller refractive index than a layer adjacent thereto. The low refractive index layer LRL may be formed of a single layer or a plurality of layers.

An electronic device in an embodiment includes color filters to enhance light extraction efficiency and reduce external light reflection, and include an overcoat layer on the color filters to prevent or reduce the intrusion of moisture and/or impurities thereinto, thus preventing reducing pixel degradation and/or color bleeding, thereby providing superior display quality.

In the above, description has been made with reference to embodiments of the present disclosure, but those skilled or of ordinary skill in the art may understand that various suitable modifications and changes may be made to the present disclosure insofar as such modifications and changes do not depart from the spirit and technical scope of the present disclosure set forth in the appended claims and equivalents thereof. Therefore, the technical scope of the present disclosure is not to be limited to the contents stated in the detailed description of the specification, but should be determined by the appended claims and equivalents thereof.

What is claimed is:

1. An electronic device comprising:
a display panel;
a color filter layer on the display panel; and
an overcoat layer on the color filter layer,
wherein the overcoat layer comprises:
a first organic overcoat layer on the color filter layer and comprising a polymer derived from a resin composition comprising a base resin and a polyol compound;
a first inorganic overcoat layer on the first organic overcoat layer; and
a second organic overcoat layer on the first inorganic overcoat layer and comprising the polymer.

2. The electronic device of claim 1, wherein the first inorganic overcoat layer comprises at least one of silicon oxide or silicon nitride.

3. The electronic device of claim 1, wherein the first inorganic overcoat layer comprises at least one of a first inorganic film comprising silicon oxide or a second inorganic film comprising silicon nitride.

4. The electronic device of claim 3, wherein the first inorganic overcoat layer has the first inorganic film and the second inorganic film alternately stacked on the first organic overcoat layer in a plurality of layers.

5. The electronic device of claim 1, wherein the first inorganic overcoat layer comprises:
a first inorganic film on the first organic overcoat layer and comprising silicon oxide;
a second inorganic film on the first inorganic film and comprising silicon nitride;
a third inorganic film on the second inorganic film and comprising silicon oxide; and
a fourth inorganic film on the third inorganic film and comprising silicon nitride.

6. The electronic device of claim 1, wherein the overcoat layer further comprises a low refractive index layer on the second organic overcoat layer.

7. The electronic device of claim 1, wherein the overcoat layer further comprises:
a second inorganic overcoat layer on the second organic overcoat layer; and
a third organic overcoat layer on the second inorganic overcoat layer.

8. The electronic device of claim 7, wherein the second inorganic overcoat layer comprises at least one of silicon oxide or silicon nitride.

9. The electronic device of claim 1, wherein the first organic overcoat layer and the second organic overcoat layer each have a thickness of about 0.5 μm to about 20 μm.

10. The electronic device of claim 1, wherein the color filter layer comprises a first color filter that transmits red light, a second color filter that transmits green light, and a third color filter that transmits blue light, and
the first organic overcoat layer is in direct contact with the first color filter, the second color filter, and the third color filter.

11. The electronic device of claim 10, wherein the second color filter comprises a colorant which exhibits an emission wavelength spectrum having a full width at half maximum (FWHM) of about 70 nm or less, and
the third color filter comprises a colorant which exhibits an emission wavelength spectrum having a full width at half maximum (FWHM) of about 100 nm or less.

12. The electronic device of claim 1, wherein the base resin comprises at least one of a polysilsesquioxane compound or a polysiloxane compound.

13. The electronic device of claim 1, wherein the base resin comprises a polysilsesquioxane compound, and
the polysilsesquioxane compound is provided in an amount of about 30 wt % to about 50 wt % with respect to a total weight of the resin composition.

14. The electronic device of claim 1, wherein the polyol compound is provided in an amount of greater than about 0 wt % and about 10 wt % or less with respect to a total weight of the resin composition.

15. An electronic device comprising:
a display panel that outputs source light and comprises a first light emitting region, a second light emitting region, and a third light emitting region, which are spaced apart on a plane and sequentially provided in a first direction; and
a light control panel on the display panel and that transmits the source light or converts a wavelength of the source light,
wherein the light control panel comprises:
first to third color filters provided corresponding to the first to third light emitting regions, respectively; and
an overcoat layer on the first to third color filters,
the overcoat layer comprising:
a first organic overcoat layer that covers the first to third color filters;
a second organic overcoat layer that faces the first organic overcoat layer; and
a first inorganic overcoat layer between the first organic overcoat layer and the second organic overcoat layer.

16. The electronic device of claim 15, wherein the first inorganic overcoat layer comprises:
at least one first inorganic film comprising silicon oxide; and
at least one second inorganic film comprising silicon nitride.

17. The electronic device of claim 16, wherein in the first inorganic overcoat layer, the first inorganic film and the second inorganic film are alternately stacked in a plurality of layers.

18. The electronic device of claim 15, wherein the light control panel further comprises a light control layer between the display panel and the first to third color filters,
the light control layer comprising:
a first light control portion corresponding to the first light emitting region and comprising a first quantum dot that converts the source light into light of a different wavelength;
a second light control portion corresponding to the second light emitting region and comprising a second quantum dot that converts the source light into light of a different wavelength; and
a third light control portion corresponding to the third light emitting region and that transmits the source light.

19. The electronic device of claim 15, wherein the first organic overcoat layer and the second organic overcoat layer each comprise a polymer derived from a resin composition comprising a polysilsesquioxane compound and a polyol compound.

20. The electronic device of claim 14, wherein the light control panel further comprises an anti-reflection layer on the overcoat layer.
